(19) United States
(12) Patent Application Publication
(10) Pub. No.: US 2008/0031029 A1
(43) Pub. Date: Feb. 7, 2008

(54) Semiconductor memory device with split bit-line structure

(75) Inventor: Jhon Jhy Liaw, Hsin Chu (TW)

Correspondence Address: L. Howard Chen, Esq.;Kirkpatrick & Lockhart Preston Gates Ellis LLP, Suite 1700, 55 Second Street, San Francisco, CA, 94104, US

(73) Assignee: Taiwan Semiconductor Manufacturing Co., Ltd.

(21) Appl. No.: 11/499,278

(22) Filed: Aug. 5, 2006

(51) Int. Cl. G11C 11/00; G11C 5/06; G11C 7/00; G11C 11/24

(52) U.S. Cl. 365/63; 365/154; 365/202; 365/149

(57) ABSTRACT

A semiconductor memory device with split bit-line structure is disclosed to realize compact high-density memory device with high speed. The semiconductor memory device includes a first bit-line coupled to a first memory cell, and a second bit-line coupled to a second memory cell. The first and the second bit-lines are formed on different metallization layers. The first and the second memory cells are in the same column of a memory cell array.

### BACKGROUND

The present invention relates generally to a semiconductor memory device, and more particularly to a volatile Random Access Memory (RAM) with improved speed and data sensing capabilities.

RAM is typically used for temporary storage of data in a computer system. There are several types of volatile RAM, including Static RAM (SRAM), and Dynamic RAM (DRAM). SRAM retains its memory state without refreshing as long as power is supplied to the cells, while DRAM must be continually rewritten in order to retain the data.

The layout of the basic memory cells of a semiconductor memory device determines the efficiency of the memory cell array area. FIG. 1 shows a typical structure of a semiconductor memory device having a two-dimensional array of memory cells. Referring to FIG. 1, the memory addresses A0˜A3 are decoded by the decoder 12 to enable a specific word-line 16 (WL₀˜WL_{N}). As the addressed word-line 16 is driven, the corresponding memory cells 11 can be accessed by bit-lines (BL) 13 and complementary bit-lines (BLB) 14 for read/write operations. BL 13 and BLB 14 accessible to the memory cells 11 of the same column are conventionally formed on the same metallization layer. Sense amplifiers (SA) 15 are access transistors coupled to a column of the memory cells 11 for amplifying signals coming off BL 13 and BLB 14.

The memory cell 11 can be a DRAM, 6-T SRAM or 8-T SRAM cell. A DRAM cell array includes cells consisting of capacitors. Each capacitor retains one bit of data, and is addressed by row and column decoders. The structure of a DRAM cell is simpler than that of an SRAM cell. A basic CMOS (Complementary Metal Oxide Semiconductor) type SRAM cell consists of two cross coupled inverters and two access transistors connecting the two inverters to complementary bit-lines. The two access transistors are simple NMOS (N-channel Metal Oxide Semiconductor) pass-transistors, controlled by word-lines. Thus, an SRAM cell retains one of its two possible steady states of “0” and “1” when the two pass transistors are turned off.

SRAM is widely used as an on-chip memory for system-on-chips (SoCs) for electronic devices. As electronic devices become more functional, memory of higher device density is demanded. However, there are various challenges in maximizing the device density for logic circuits and memory cells. For instance, the increase in rows will induce higher bit-line metal coupling capacitance, and degrade bit-line and bit-line-bar differential speed. Moreover, the increase in rows will also decrease Ion and Ioff ratio of bit-line and complementary bit-line in the worst case scenario. This problem is critical especially when it degrades the sensing margin of the sense amplifiers in high performance devices. Likewise, in DRAM technology, the bit-line coupling capacitance dominates the sensing speed and sensing margin. Consequently, there is a trade-off between speed and density. A high speed design needs shorter bit-lines and larger cell capacitors, while the high-density design will need smaller cell capacitance and more bits per bit-line.

As such, what is needed is a new structure for a semiconductor memory device to realize compact high-density memory devices with a high speed and a high data sensing margin. It is also desirable to provide a new manufacturing process for forming the new structure without significantly changing the existing process steps, thereby saving manufacturing costs.

### SUMMARY

In view of the foregoing, a semiconductor memory device with split bit-line structure is disclosed. The semiconductor memory device of the invention includes a first bit-line coupled to a first memory cell, and a second bit-line coupled to a second memory cell. The first and the second bit-lines are formed on different metallization layers and of different lengths. Moreover, the first and the second memory cells are in the same column of the two-dimensional memory cell array.

In a manufacturing process that includes the steps of forming four metallization layers, the process for forming the semiconductor memory device with the split bit-line structure includes the following steps. Firstly, form a local interconnection for a two-dimensional array of memory cells on a first metallization layer. Then, form a first group of bit-lines on a second metallization layer for a first group of memory cells. Thereafter, form a plurality of word-lines for the two-dimensional array of memory cells on a third metallization layer. Finally, form a second group of bit-lines on a fourth metallization layer for a second group of memory cells.

The construction and method of operation of the invention, however, together with additional objectives and advantages thereof will be best understood from the following description of specific embodiments when read in connection with the accompanying drawings.

### BRIEF DESCRIPTION OF THE DRAWINGS

FIG. 1 illustrates a conventional two-dimensional array of semiconductor memory cells.

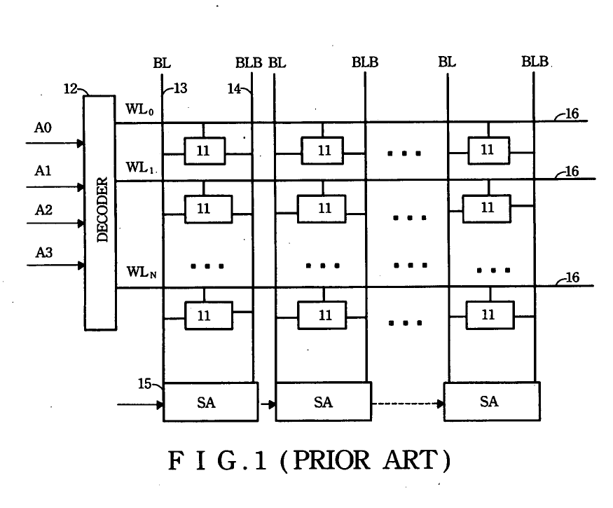

FIG. 2 illustrates a two-dimensional array of SRAM cells according to one embodiment of the present invention.

FIG. 3 illustrates a 6-T SRAM cell with a split bit-line structure according to another embodiment of the present invention.

FIG. 4 illustrates a 6-T SRAM cell with a split bit-line structure according to another embodiment of the present invention.

FIG. 5 illustrates an 8-T SRAM cell with a split bit-line structure according to another embodiment of the present invention.

FIG. 6 illustrates an 8-T SRAM cell with a split bit-line structure according to another embodiment of the present invention.

FIG. 7 illustrates a two-dimensional array of DRAM cells according to another embodiment of the present invention.

FIG. 8 illustrates a DRAM cell with a split bit-line structure according to another embodiment of the present invention.

FIG. 9 illustrates a DRAM cell with a split bit-line structure according to another embodiment of the present invention.

### DESCRIPTION

As the 128-bit bit-line design has almost reached its design limitation in the 90 nm or 65 nm generation of semiconductor manufacturing technology, new structures for memory devices are needed to achieve a high speed and a high data sensing margin. The present invention provides an improved bit-line structure that can overcome the design limitation and solve the problems of bit-line coupling capacitance and bit-line loading effects without compromising on the bit-line/bit-line-bar differential speed.

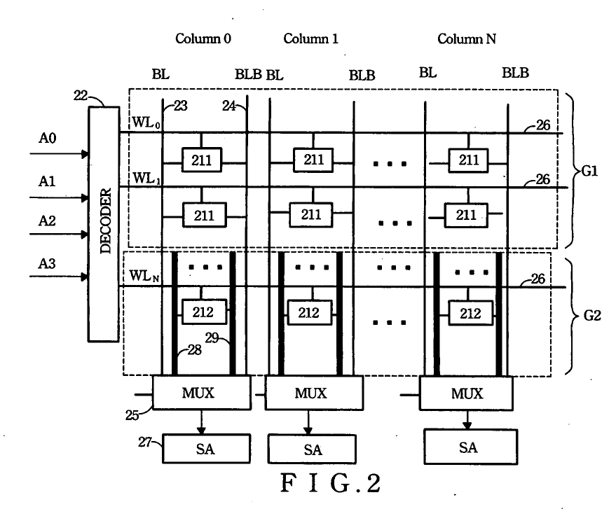

FIG. 2 shows architecture of a semiconductor memory device consisting of SRAM cells according to one embodiment of the present invention. The SRAM cells 211 and 212 are grouped into two groups G1 and G2, respectively. The SRAM cells 211 and 212 can be implemented as 6T-SRAM cells or 8T-SRAM cells.

The split bit-line architecture of column 0 is substantially the same as that of the remaining columns. The memory cells 211 in group 1 (G1) are coupled to a pair of bit-lines 23 and 24. The memory cells 212 in group 2 (G2) are coupled to a pair of bit-lines 28 and 29. The bit-lines 28 and 29 are illustrated in bold lines, and the bit-lines 23 and 24 are illustrated in regular lines. The bit-lines 23 and 24 and the bit-lines 28 and 29 are formed on different metallization layers. The ratio between the length of the bit-lines 28, 29 and the length of the bit-lines 23, 24 ranges approximately from ⅓ to ⅔. In a preferred embodiment, the length of the pair of bit-lines 28 and 29 is about one-half of the length of the bit-lines 23 and 24. The memory cells 211 can only be accessed by the bit-lines 23, 24, and the memory cells 212 can only be accessed by bit-lines 28, 29.

The SRAM cells 211 and 212 of column 0 are accessible by a plurality of word-lines 26 (WL₀˜WL_{N}), the first pair of bit-lines 23 and 24, and the second pair of bit-lines 28 and 29. The bit-lines 23, 24, 28 and 29 are connected to a multiplexer 25, which selectively passes signals from the bit-lines 23, 24, 28, 29 to a sense amplifier 27, which further amplifies the signals for data read operation.

The resistance of each bit-line causes a delay in cell access time. The longer the bit line, the higher the capacitance induced by the bit-line. By grouping the memory cells into two or more groups, the bit-lines can be shortened, thereby improving the speed of the memory device. In an SRAM device, the RC delay of each bit-line depends on its length and the number of pass gate devices connected thereto. A shorter bit-line and a fewer number of pass gate devices can reduce the RC delay, thereby increasing the memory operation speed. As such, the operation speed of the proposed SRAM device can be increased, because in the length of bit-line 28 or 29 there is only one half of that of a conventional bit-line, and the number of pass gate devices connected to bit-lines 23 and 24 are only one half of that in a conventional design. Moreover, since bit-lines 23/24 and bit-lines 28/29 are constructed on separate metal layers, they can be made wider as each metal layer is less crowded as opposed to conventional ones. This also helps reduce the RC delay and improve the memory operation speed.

There are several possible manufacturing processes for constructing the split bit-line structure of FIG. 2. In one embodiment of the invention where a semiconductor substrate has at least four metallization layers, a local interconnection for each cell is formed on the first metallization layer overlying the substrate. Each pair of bit-lines 28 and 29 directly connected to memory cells 212 of group 2 (G2) is formed on the second metallization layer above the first metallization layer. The V_{CC} lines are also formed among the bit-lines and their complements on the second metallization layer. The word-lines for the memory array are formed on the third metallization layer above the second metallization layer. The V_{SS} lines can be formed between the word-lines on the third metallization layer. Each pair of bit-lines 23 and 24 directly connected to memory cells 211 of group 1 (G1) is formed on the fourth metallization layer above the third metallization layer.

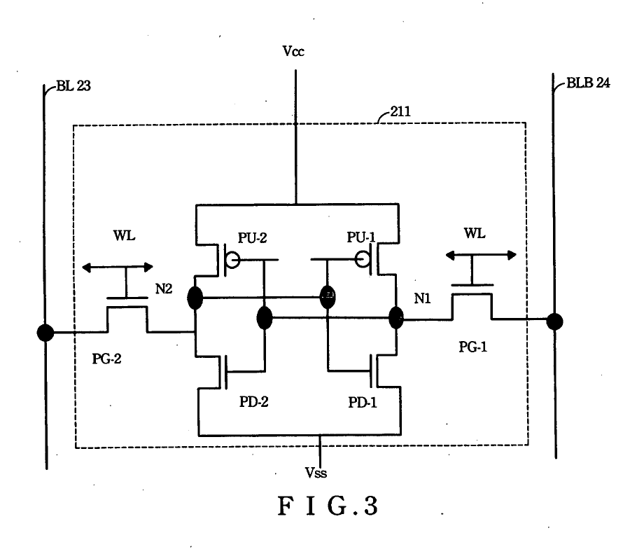

Refer to FIG. 3 for the detailed structure of a CMOS type 6-T SRAM cell 211 of group 1 (G1). The 6T-SRAM cell 211 consists of a first pass-gate transistor PG-1, a second pass-gate transistor PG-2, and a first inverter comprised of a first pull-up transistor PU-1 and a first pull-down transistor PD-1, and a second inverter comprised of a second pull-up transistor PU-2 and a second pull-down transistor PD-2.

The two inverters of the memory cell 211 contain two complementary nodes, N1 and N2. N1 is coupled to the gate of the second pull-up transistor PU-2. N2 is coupled to the gate of the first pull-up transistor PU-1. Thus, the values stored in the two nodes will be complementary to each other. When the NMOS second pull-down transistor PD-2 is turned on, any charge stored at node N2 will be discharged to ground. When N2 is low, the PMOS (P-channel Metal Oxide Semiconductor) first pull-up transistor PU-1 is on, and the voltage at N1 is pulled up to a high level. The gates of the first pass-gate transistor PG-1 and the second pass-gate transistor PG-2 are electrically coupled to a word-line (WL) to control reading data from and writing data to the memory cell 211. Values stored at N1 and N2 can be read from a bit-line (BLB) 24 and a complementary bit-line (BL) 23, respectively.

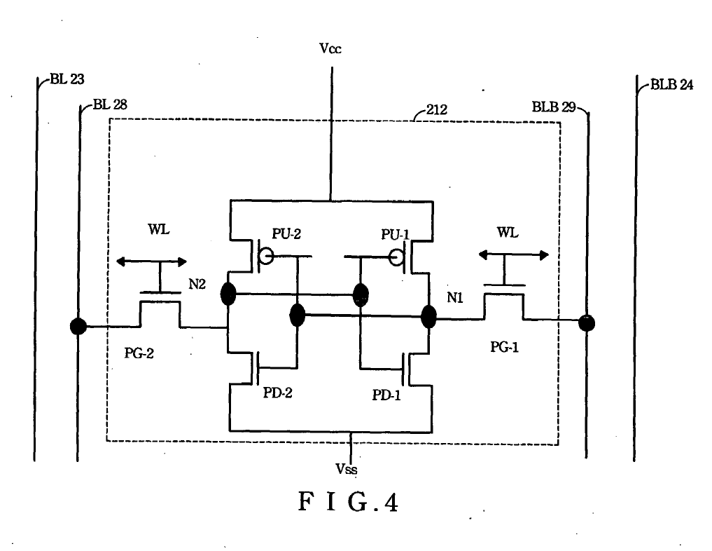

Refer to FIG. 4 for the detailed structure of a CMOS type 6-T SRAM cell 212 of group 2 (G2). The SRAM cell 212 is coupled to the bit-lines 28 and 29 and not accessible by bit-lines 23 and 24. The pair of bit-lines 23 and 24 extends through the SRAM cell 212 and is connected to the multiplexer 25 (shown in FIG. 2). The pair of bit-lines 23 and 24 are formed on a different metallization layer from that of bit-lines 28 and 29.

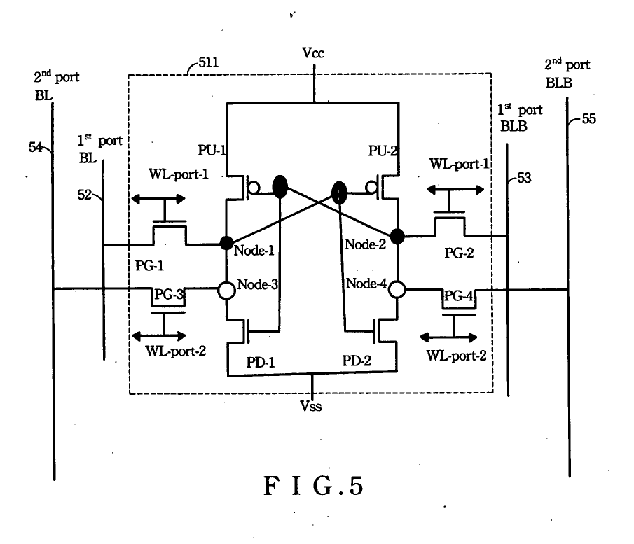

According to another embodiment of the invention, the split bit-line structure is also applicable to 8-T SRAM cells. Refer to FIG. 5 for an enlarged view of a dual-port 8-T SRAM cell 511 of group 1 (G1). In operation, the 8T-SRAM cell 511 operates substantially in the same way as the 6T-SRAM described above, except that the 8T-SRAM cell 511 includes two bit-lines, two complementary bit-lines, and two word-lines. The two bit-lines, i.e., the first port bit-line 52 and the second port bit-line 54, and the two complementary bit-lines, i.e., the first port complementary bit-line 53 and the second port complementary bit-line 55, function as data lines for reading data from and writing data to the 8T-SRAM cell 511. The two word-lines WL-port-1 and WL-port-2 control the pass gate transistors PG-1, PG-2, PG-3, and PG4. The two additional transistors PG-3 and PG-4 provides access to Node-3 and Node4.

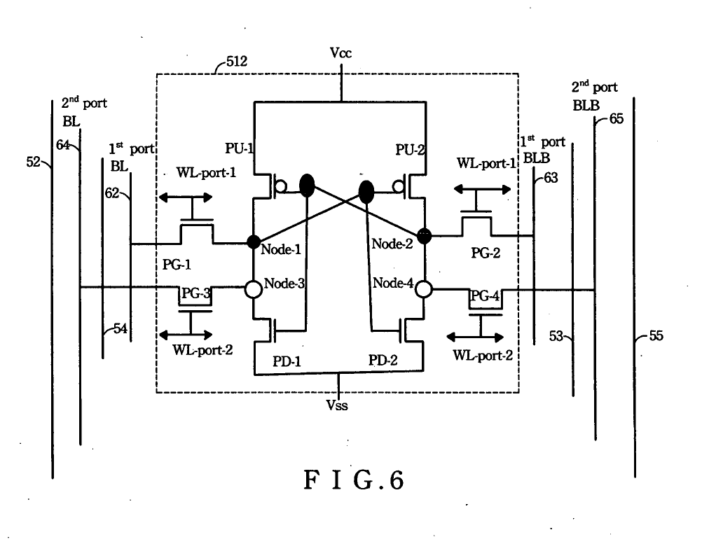

FIG. 6 illustrates an enlarged view of a dual-port 8-T SRAM cell 512 of group 2 (G2). The structure of an 8-T SRAM cell 512 is basically the same as that in FIG. 5. The pairs of bit-lines 52, 53 and 54, 55 are not directly connected to 8T-SRAM cell 512 of group 2. The two pairs of bit-lines 62, 63, and 64, 65 and the two pairs of bit-lines 52, 53, and 54, 55 are formed on different metallization layers. The process of forming the dual port 8-T SRAM cell is similar to the process as described above for 6-T SRAM cells.

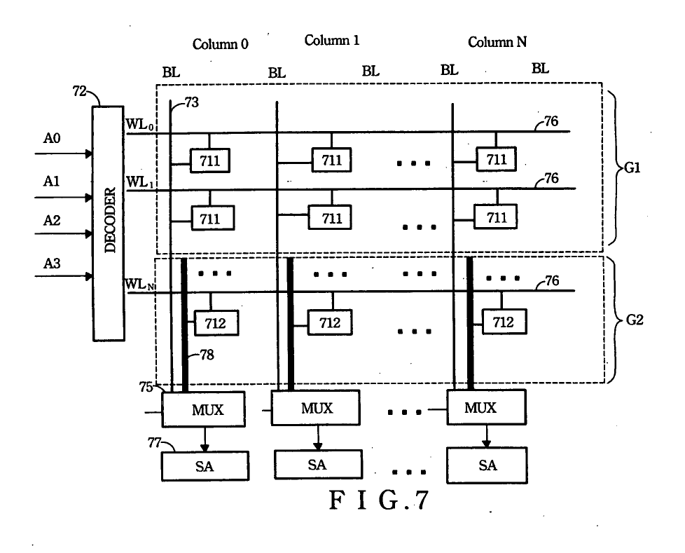

According to yet another embodiment of the invention, the split bit-line structure is also applicable to DRAMs. FIG. 7 illustrates a DRAM cell array with the spit bit-line structure. The split bit-line structure for DRAM cells is substantially the same as the structure shown in FIG. 2, except that there is no complementary bit-line for DRAM cells. A typical DRAM cell stores one bit of data in a capacitor. Take the DRAM cells of column 0 as an example. The DRAM cells are grouped into group 1 (G1) and group 2 (G2). Accordingly, the bit-line 73 can access only to the DRAM cells of group 1, while the bit-line 78 can only access to the DRAM cells 712 of group 2. The bit-lines 73 and 78 are formed on different metallization layers. A multiplexer 75 selectively passes signals from bit-lines 73 and 78 to the sense amplifier 77.

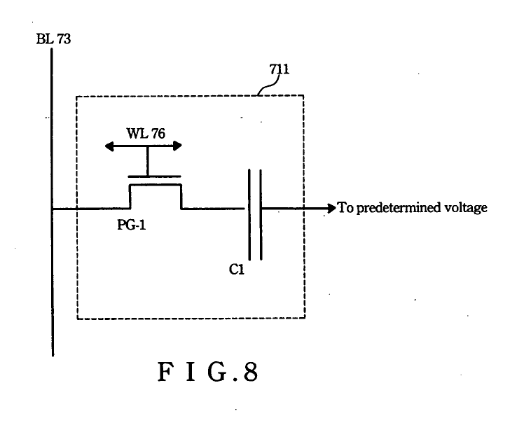

FIG. 8 illustrates a DRAM cell 711 of group 1 (G1). The DRAM cell 711 is accessible by word-line 76 and bit-line 73. In write operation, the word-line 76 is asserted to turn on the NMOS transistor PG-1 for charging the capacitor C1. In read operation, the word-line is asserted to turn on the NMOS transistor PG-1 for discharging the capacitor C1 through the bit-line 73.

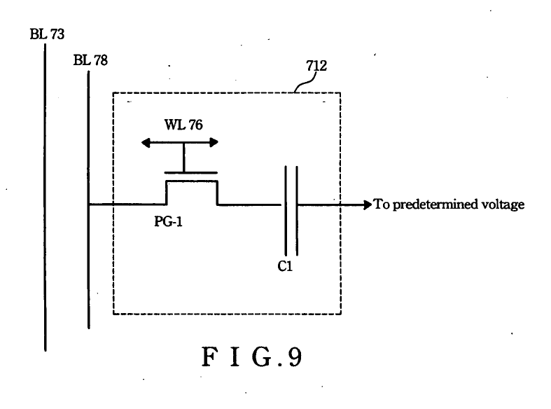

FIG. 9 illustrates a DRAM cell 712 of group 2 (G2). The DRAM cell 712 is accessible by word-line 76 and bit-line 78. The bit-line 73 and bit-line 78 are on different metallization layers. A typical DRAM layout may not need four metallization layers. In that case, the bit-line 73 of group 1 (G1) may be formed on the third metallization layer, while the bit-line 78 of group 2 (G2) on the second metallization layer. The split bit-line structure for DRAM cells are substantially the same as that for SRAM cells. Accordingly, the bit-line 73 of group 1 (G1) is about twice as long as the bit-line 78 of group 2 (G2).

With the improved bit-line structure, the semiconductor memory device significantly improves its performance by reducing delay time up to 50% and bit-line leakage loading effect to 50%, as opposed to a conventional memory device. Moreover, the improved bit-line structure can also increase array area efficiency and the sensing margin.

The above illustration provides many different embodiments or embodiments for implementing different features of the invention. Specific embodiments of components and processes are described to help clarify the invention. These are, of course, merely embodiments and are not intended to limit the invention from that described in the claims.

Although the invention is illustrated and described herein as embodied in one or more specific examples, it is nevertheless not intended to be limited to the details shown, since various modifications and structural changes may be made therein without departing from the spirit of the invention and within the scope and range of equivalents of the claims. Accordingly, it is appropriate that the appended claims be construed broadly and in a manner consistent with the scope of the invention, as set forth in the following claims.

What is claimed is:

1. A semiconductor memory device having a cell array, comprising:
a first bit-line coupled to a first memory cell; and
a second bit-line coupled to a second memory cell disposed in the same column as the first memory cell in the cell array; and
wherein the first and the second bit-lines are formed on different metallization layers and of different lengths.

2. The semiconductor memory device of claim 1 further comprising:
a sense amplifier; and
a multiplexer coupled to the sense amplifier for selectively passing signals from the first bit-line and the second bit-line to the sense amplifier.

3. The semiconductor memory device of claim 1, wherein the first bit-line and the second bit-line are formed on a substrate with at least three metallization layers.

4. The semiconductor memory device of claim 1, wherein the first bit-line is formed on the same metallization layer as where one or more power supply lines are formed, and the second bit-line is formed on a metallization above the first bit-line.

5. The semiconductor memory device of claim 1, wherein the length of the first bit-line is about one half of the length of the second bit-line.

6. The semiconductor memory device of claim 1, wherein the first memory cell and the second memory cell are 6-transistor static random access memory cells.

7. The semiconductor memory device of claim 1, wherein the first memory cell and the second memory cell are 8-transistor static random access memory cells.

8. The semiconductor memory device of claim 1, wherein the first memory cell and the second memory cell are dynamic random access memory cells.

9. A static random access memory (SRAM) cell array structure comprising:
a first bit-line formed on a first metallization layer; and
a second bit-line formed on a second metallization layer,
wherein the first bit-line and the second bit-line are of different lengths, and coupled to different groups of cells in the same column of the cell array.

10. The SRAM cell array structure of claim 9 further comprising:
a sense amplifier; and
a multiplexer coupled to the sense amplifier for selectively passing signals from the first bit-line and the second bit-line to the sense amplifier.

11. The SRAM cell array structure of claim 9, further comprising:
a first complementary bit-line corresponding to the first bit-line on the first metallization layer; and
a second complementary bit-line corresponding to the second bit-line on the second metallization layer.

12. The SRAM cell array structure of claim 9, wherein the first bit-line and the second bit-line are formed on a substrate with at least three metallization layers.

13. The SRAM cell array structure of claim 9, wherein the length of the first bit-line is about one half of the length of the second bit-line.

14. The SRAM cell array structure of claim 9, wherein the first bit-line is formed on the same metallization layer as where one or more power supply lines are formed, and the second bit-line is formed on a metallization above the first bit-line.

15. The SRAM cell array structure of claim 9, wherein the cells are 6-transistor SRAM cells or 8-transistor SRAM cells.

16. A dynamic random access memory (DRAM) cell array structure comprising:
a first bit-line formed on a first metallization layer; and
a second bit-line formed on a second metallization layer,
wherein the first bit-line and the second bit-line are of different lengths, and coupled to different groups of cells in the same column of the cell array.

17. The DRAM cell array structure of claim 16 further comprising:
a sense amplifier; and
a multiplexer coupled to the sense amplifier for selectively passing signals from the first bit-line and the second bit-line to the sense amplifier.

18. The DRAM cell array structure of claim 16, wherein the first bit-line is formed on the same metallization layer as where one or more power supply lines are formed, and the second bit-line is formed on a metallization above the first bit-line.

19. The DRAM cell array structure of claim 16, wherein the length of the first bit-line is about one half of the length of the second bit-line.
